(19) United States
(12) Patent Application Publication
(10) Pub. No.: US 2006/0179382 A1
(43) Pub. Date: Aug. 10, 2006

(54) Method and circuit for implementing array bypass operations without access penalty

(75) Inventors: Paul A. Bunce, Poughkeepsie, NY (US); John D. Davis, Wallkill, NY (US); Donald W. Plass, Poughkeepsie, NY (US)

Correspondence Address: CANTOR COLBURN LLP-IBM POUGHKEEPSIE, 55 GRIFFIN ROAD SOUTH, BLOOMFIELD, CT, 06002, US

(73) Assignee: International Business Machines Corporation, Armonk, NY (US)

(21) Appl. No.: 11/054,737

(22) Filed: Feb. 10, 2005

(51) Int. Cl. G01R 31/28; G06F 11/00

(52) U.S. Cl. 714/737

(57) ABSTRACT

A method and circuit for implementing array bypass operations without access penalty for a random access memory circuit. The random access memory circuit includes a circuit array of memory cells, a read circuit, a data output register, a data input register, a write circuit, a write control register, a bypass control register, a row decoder, and an address register. The method includes directly coupling the read circuit to the data output register and coupling-the bypass control register to the row detector. The bypass control register issues a bypass signal to the row decoder. The bypass signal includes one of an active bypass signal and an inactive bypass signal. If the bypass signal issued is inactive, then one of a read operation and a write-through operation without bypass is performed. If the bypass control signal issued is active, then a write-through operation is performed in bypass mode.

### BACKGROUND OF THE INVENTION

1. Field of the Invention

The invention relates generally to random access memory circuits, and more particularly, to a method and circuit for implementing array bypass operations without access penalty.

2. Description of Background

In the process of computer operations, it is sometimes necessary to “bypass” a random access memory (RAM) array. In bypass mode, data is sent from a data input register to a data out register without the contents of the RAM being updated. This is typically accomplished via a bypass control register that provides an active bypass signal to a bypass multiplexor. In the presence of an active bypass signal, a bypass multiplexor electrically decouples a read circuit from a data output register and electrically couples a data input register to a data output register. In order to prevent the RAM contents from being updated, a write control register is conditioned to withhold an active write signal to a write circuit, thus preventing the contents of the RAM from being updated.

One drawback associated with the aforementioned bypass implementation relates to the bypass multiplexor. For example, in order for data to be sent-from the read circuit to the data output register, it must pass through the bypass multiplexor. The process of transmitting the data signal through the bypass multiplexor is time consuming, which ultimately results in a negative effect on the overall performance of the RAM, as well as the computer system as a whole. Furthermore, in addition to this degradation in performance, the bypass multiplexor utilizes valuable space on the circuit chip, which results in a larger chip size. Since the size of the chip is directly proportional to the cost of the chip, this ultimately leads to a more costly chip. Additionally, the bypass multiplexor typically requires a wire that connects the data input register to the bypass multiplexor. In any chip design, wires are a precious resource, the conservation of which is a desirable attribute.

### SUMMARY OF THE INVENTION

The shortcomings of the prior art are overcome and additional advantages are provided through the provision of a method and circuit for implementing array bypass operations without access penalty.

The random access memory circuit includes a circuit array of memory cells, a read circuit, a data output register, a data input register, a write circuit, a write control register, a bypass control register, a row decoder, and an address register. The method includes directly coupling the read circuit to the data output register and coupling the bypass control register to the row detector. The bypass control register issues a bypass signal to the row decoder. The bypass signal is one of an active bypass signal or an inactive bypass signal. If the bypass signal issued is inactive, then one of a read operation and a write-through operation is permitted. If the bypass signal issued is active, then a write-through operation is performed in bypass mode.

System and computer program products corresponding to the above-summarized methods are also described and claimed herein.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 is a is a schematic diagram of a basic random access memory (RAM) circuit including write-through and bypass support elements in the prior art;

FIG. 2 is a is a schematic diagram of a RAM circuit including write-through and bypass support elements in exemplary embodiments;

FIG. 3 is a flow diagram describing a read operation of a RAM in exemplary embodiments;

FIG. 4 is a flow diagram describing a write-through operation of a RAM in bypass mode in exemplary embodiments; and

FIG. 5 is a diagram illustrating a modified clock chopper component of a row decoder used in implementing bypass operations in exemplary embodiments.

### DETAILED DESCRIPTION OF THE INVENTION

In accordance with exemplary embodiments, a method and circuit for implementing array bypass operations without access penalty is provided. The bypass operations are performed without utilization of a bypass multiplexor and without requiring a physical connection (e.g., wire) traditionally used for coupling a data input register to a bypass muliplexor, thus, maximizing chip space, processing speed, and ultimately reducing costs associated with manufacturing. As indicated above, read and write-through operations that are typically performed on a circuit system may, in some situations, require bypass. It will be understood that a write-through operation without bypass results in the random access memory being updated, while a write-through operation with bypass results in no update to the random access memory.

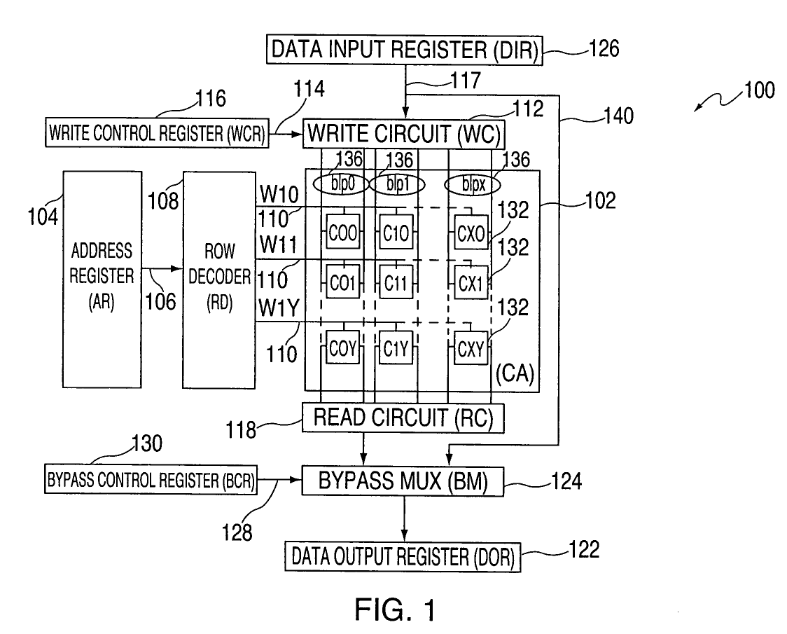

Turning now to FIG. 1, a RAM circuit 100 including write-through and bypass support elements as provided in the prior art will now be described for background purposes. A circuit array 102 is an array of memory cells x columns wide by y rows high. An address register (AR) 104 provides a binary encoded address 106 to a row decoder 108. Depending on the binary value stored in address register 104, the row decoder 108 provides an active signal to one, and only one, of the wordlines 110 labeled Wl0 thru Wly. A write circuit (WC) 112 is provided, which, in the absence of an active write signal 114 provided by a write control register (WCR) 116, is electrically decoupled from the array 102 of memory cells 132. A read circuit (RC) 118 is provided in the RAM circuit 100 diagram of FIG. 1, and receives inputs from the array 102 of memory cells. Also included in the RAM circuit 100 is a data output register (DOR) 122 which holds resultant binary values of the RAM operation. A bypass multiplexor (BM) 124 electrically couples the data input register (DIR) 126 or the read circuit 118 to the data output register 122, depending upon whether or not it receives an active bypass signal 128 from a bypass control register (BCR) 130.

A read operation occurs in the absence of an active write signal. The row decoder 108 receives a binary address 106 from the address register 104 and outputs an active signal onto one of the wordlines 110. The memory cells 132 connected the active wordline (e.g., one of wordlines 110) provide a weak signal to the bitline pairs BLP0-BLPx (136). This signal is received by the read circuit 118 at the base of the bitline pairs 136 and provides an input to the bypass multiplexor 124, which in turn provides an input to the data output register 122.

A write-through operation begins much like a read operation. The row decoder 108 receives a binary address 106 from the address register 104 and outputs an active signal on to one of the wordlines 110. The write operation occurs in the presence of an active write signal 114 provided to the write circuit 112 by the write control register 116. In the presence of the active write signal 114, the write circuit 112 receives binary values from the data input register 126 and provides a very strong differential signal to the bitline pairs BLP0-BLPn. This signal is strong enough to overpower the weak signal provided by the memory cells 132 selected via their connection to the active wordline (one of wordlines 110). This induces the memory cells to be written to the binary values provided to the write circuit 112. This same signal (provided by the write circuit) is received by the read circuit 118, which in turn provides an input to the bypass multiplexor 124, which in turn provides an input to the data output register 122.

Both of the above read and write-through operations occur in the absence of an active bypass signal by received by the bypass multiplexor 124 from the bypass control register 130. In the absence of an active bypass signal, the bypass multiplexor 124 electrically couples the read circuit 118 to the data output register 122. The absence of this active signal also electrically decouples the data input register 126 from the data output register 122.

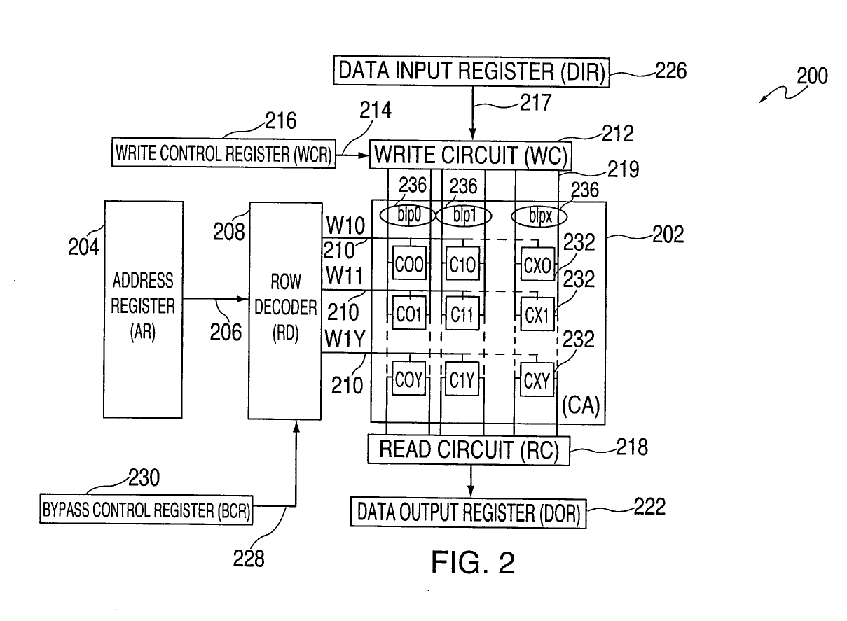

Turning now to FIG. 2, a RAM circuit 200 including write-through and by-pass support elements in accordance with exemplary embodiments will now be described. The RAM circuit elements of FIG. 2 operate similarly to those described in the RAM circuit of FIG. 1, except as otherwise provided herein. In the RAM circuit 200 of FIG. 2, the bypass multiplexor described in FIG. 1 has been removed, along with the wire 140 from the data input register to the bypass multiplexor. The read circuit (RC) 218 is now directly coupled to the data output register (DOR) 222. The bypass control register (BCR) 230 now provides an input directly to the row decoder (RD) 208. This input is referred to herein as a bypass signal 228. The bypass signal 228 may be active or inactive. An active bypass signal asserts that the circuit system is in bypass mode, while an inactive bypass signal indicates that the circuit system is not in bypass mode.

When the bypass control register 230 provides an inactive bypass signal 228 to the row decoder 208, the read and write operations performed are similar to those described above with respect to FIG. 1 and indicates that the read/write operation does not require any bypass. However, the data output register 222 receives its input directly from the read circuit 218. This eliminates the delay otherwise encountered when passing the signal through the bypass multiplexor as is described in FIG. 1. When the bypass control register 230 provides an active bypass signal 228 to the row decoder 208, the row decoder 208 is inhibited from providing an active signal to any of the wordlines 210. This, in turn, modifies both the read and write operations with respect to the operations described with respect to FIG. 1.

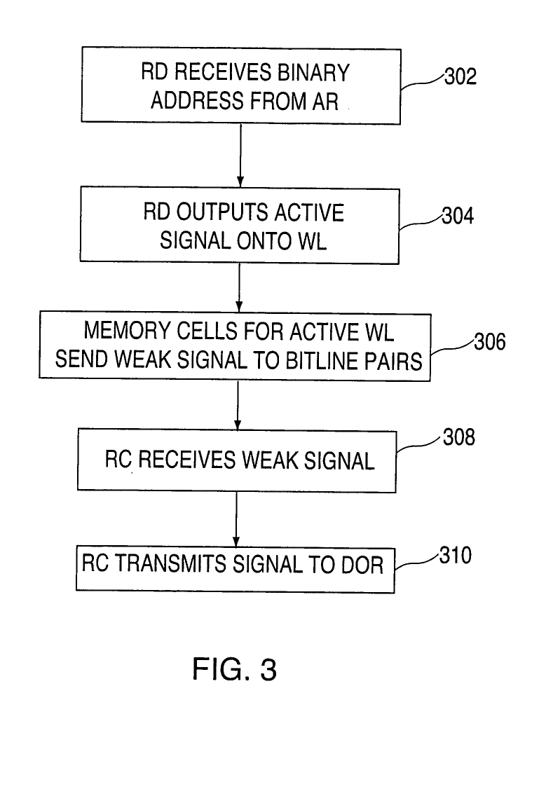

While the receipt of the active bypass signal by the row decoder 208 will modify both the read and the write operations, it is desirable for this application to only allow an active bypass signal 228 to be provided to the row decoder 208 during a write operation and to force the bypass signal 228 presented to the row decoder 208 to be inactive during a read operation. This may be performed by a number of different methods, as will be understood by one skilled in the art. With the bypass signal 228 never active during a read operation, the read operation is performed as described in the flow diagram of FIG. 3 in accordance with exemplary embodiments.

At step 302, row decoder 208 receives a binary address 206 from address register 204. Row decoder 208 outputs an active signal onto one of wordlines 210 at step 304. At step 306, the memory cells 232 connected to the active wordline (e.g., one of wordlines 210) provide a weak signal to the bitline pairs BLP0-BLPx (236). This weak signal is received by the read circuit 218 at the base of the bitline pairs at step 308 and provides an input directly to the data output register 222 at step 310, thus no delay penalty typically associated with passing through a bypass multiplexor is incurred.

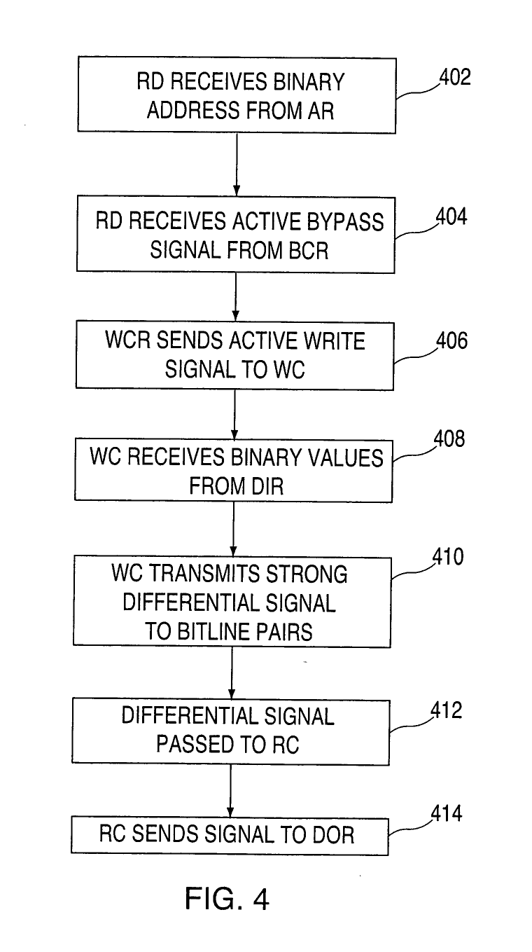

A write operation in the presence of an active bypass signal 228 is performed as described in the flow diagram of FIG. 4 in accordance with exemplary embodiments. While the process steps recited in FIG. 4 are described as occurring in a sequence, it will be understood by those skilled in the art that many of the events recited in the flow diagram of FIG. 4 may be performed in a different order (e.g., the write circuit may have the data available and be waiting for the write signal). A write operation begins much like a read operation. At step 402, row decoder 208 receives a binary address 206 from address register 204. Row decoder 208 also receives an active bypass signal 228 from bypass control register 230 at step 404. In the presence of the active bypass signal 228, the row decoder 208 does not output an active signal to any of the wordlines 210. Further, the write operation occurs during the presence of an active write signal 214, which is provided by the write control register 216 to the write circuit 212 at step 406.

In the presence of the active write signal 214, the write circuit 212 receives binary values 217 from the data input register 226 at step 408. The write circuit 212 transmits a strong differential signal 219 to bitline pairs 236 at step 410. Since the row decoder 208 has not provided an active signal to any of the wordlines 210 (due to the active bypass signal 228 provided by the bypass control register 230) there is no signal (weak or otherwise) provided by any of the memory cells 232 to be overpowered. The strong differential signal 219 provided by the write circuit 212 is passed directly to the read circuit 218 at step 412. Further, since the row decoder 208 did not provide an active signal to any of the wordlines 210, none of the memory cells 232 are induced to be written to the binary values provided by the write circuit 212, thus the contents of the RAM 200 will not be updated. The read circuit 218, having received its input from the write circuit 212, provides an input directly to data output register 222 at step 414.

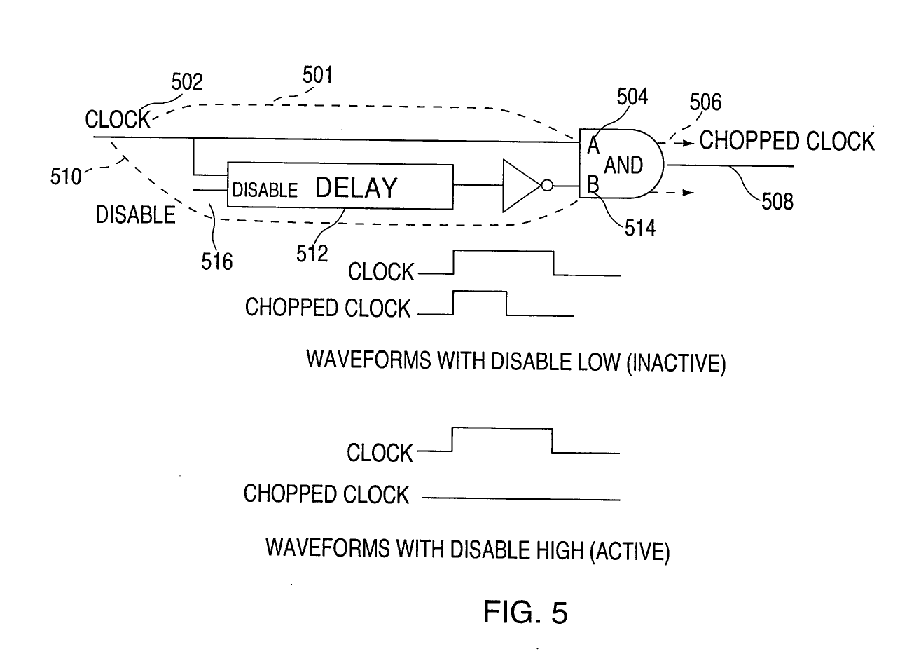

FIG. 5 is a diagram illustrating a modified clock chopper component of a row decoder (e.g., 208) used in implementing bypass operations in exemplary embodiments. A clock chopper would (in some embodiments) be used within the row decoder 208 to ultimately enable active signals to the wordline outputs. In traditional bypass operations of the prior art, the clock chopper function would receive an active signal of duration T and provide an active signal of duration less than T (approximately of duration delay). The performance critical path 501 of the clock chopper is from input 502 labeled CLOCK through the A input 504 of the AND gate 506 to the output 508 labeled CHOPPED CLOCK. The path 510 from the input 502 labeled CLOCK through the block 512 labeled DELAY to the B input 514 of the AND gate 506 is not performance critical and is used to determine the duration of the active output signal 508 labeled CHOPPED CLOCK. As shown in FIG. 5, the modified clock chopper includes DISABLE input 516 to the delay block 512. It will be understood by those skilled in the art that various methods for causing the delay block 512 to force the input B 514 of the AND logic gate 506 to be low (inactive) in the presence of an active signal on the DISABLE input 516 of the delay block 512 (thus, preventing the clock chopper from outputting an active signal of any duration to the pin labeled CHOPPED BLOCK) may be used. Providing the bypass signal of FIG. 2 to the DISABLE pin 516 of the modified clock chopper would be one method to cause the row decoder (e.g., 208) to refrain from outputting any active wordline signal in the presence of the active bypass signal (e.g., 228) thus providing one aspect of the invention.

The capabilities of the present invention can be implemented in software, firmware, hardware or some combination thereof.

As one example, one or more aspects of the present invention can be included in an article of manufacture (e.g., one or more computer program products) having, for instance, computer usable media. The media has embodied therein, for instance, computer readable program code means for providing and facilitating the capabilities of the present invention. The article of manufacture can be included as a part of a computer system or sold separately.

Additionally, at least one program storage device readable by a machine, tangibly embodying at least one program of instructions executable by the machine to perform the capabilities of the present invention can be provided.

The flow diagrams depicted herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A method for implementing array bypass operations without access penalty for a random access memory circuit, the random access memory circuit comprising a circuit array of memory cells, a read circuit, a data output register, a data input register, a write circuit, a write control register, a bypass control register, a row decoder, and an address register, the method comprising:
directly coupling the read circuit to the data output register;
coupling the bypass control register to the row detector, the bypass control register issuing a bypass signal to the row decoder, the bypass signal comprising one of an active bypass signal and an inactive bypass signal;
if the bypass signal is inactive, one of a read operation and a write-through operation performed without bypass is permitted; and
if the bypass signal issued is active, a write-through operation is performed in bypass mode.

2. The method of claim 1, wherein the read operation includes:
receiving a binary address from the address register by the row decoder;
the row decoder outputting an active signal onto a wordline associated with the circuit array;
at least one memory cell associated with the wordline providing a weak signal to bitline pairs associated with the circuit array; and
in response to receiving the weak signal by the read circuit, the read circuit provides an input to the data output register.

3. The method of claim 1, wherein the write-through operation with bypass includes:
receiving a binary address from the address register by the row decoder;
in response to receiving the active bypass signal from the bypass control register, the row decoder refrains from outputting an active signal onto a wordline associated with the circuit array;
the write control register issuing an active write signal to the write circuit;
in response to the active write signal, the data input register sends binary values to the write circuit;
in response to receiving the binary values, the write circuit issues a strong differential signal to bitline pairs associated with the circuit array, the strong differential signal overpowering any weak signals at the circuit array, if provided;
passing the strong differential signal through the bitline pairs to the read circuit; and
transmitting the resultant signal to the data output register.

4. The method of claim 3, wherein the row decoder refrains from outputting an active signal onto a wordline via a modified clock chopper component associated with the row decoder.

5. The method of claim 4, wherein the modified clock chopper component includes a disable input pin operable for causing a delay element of the modified clock chopper to force an input of a logic gate to be low in the presence of an active bypass signal on the disable input pin of the delay element.

6. A random access memory circuit for implementing array bypass operations without access penalty, the random access memory circuit comprising a circuit array of memory cells, a data input register, a write circuit, a write control register, and an address register, the random access memory circuit further comprising:
a read circuit directly coupled to a data output register;
a bypass control register directly coupled to a row detector, the bypass control register issuing a bypass signal to the row decoder, the bypass signal comprising one of an active bypass signal and an inactive bypass signal; wherein
if the bypass signal is inactive, one of a read operation and a write-through operation without bypass is permitted; and
if the bypass signal issued is active, a write-through operation is performed in bypass mode.

7. The random access memory circuit of claim 6, wherein the read operation is accomplished by:
receiving a binary address from the address register by the row decoder;
the row decoder outputting an active signal onto a wordline associated with the circuit array;
at least one memory cell associated with the wordline providing a weak signal to bitline pairs associated with the circuit array; and
in response to receiving the weak signal by the read circuit, the read circuit provides an input to the data output register.

8. The random access memory circuit of claim 6, wherein the write-through operation with bypass is accomplished by:
receiving a binary address from the address register by the row decoder;
in response to receiving the active bypass signal from the bypass control register, the row decoder refrains from outputting an active signal onto a wordline associated with the circuit array;
the write control register issuing an active write signal to the write circuit;
in response to the active write signal, the data input register sends binary values to the write circuit;
in response to receiving the binary values, the write circuit issues a strong differential signal to bitline pairs associated with the circuit array, the strong differential signal overpowering any weak signals at the circuit array, if provided;
passing the strong differential signal through the bitline pairs to the read circuit; and
transmitting the resultant signal to the data output register.

9. The random access memory circuit of claim 8, further comprising a modified clock chopper component associated with the row decoder, wherein the row decoder refrains from outputting an active signal onto a wordline via the modified clock chopper.

10. The random access memory circuit of claim 9, wherein the modified clock chopper component includes a disable input pin operable for causing a delay element of the modified clock chopper to force an input of a logic gate to be low in the presence of an active bypass signal on the disable input pin of the delay element.

11. A computer program product for implementing array bypass operations without access penalty for a random access memory circuit, the random access memory circuit comprising a circuit array of memory cells, a read circuit, a data output register, a data input register, a write circuit, a write control register, a bypass control register, a row decoder, and an address register, the computer program product including instructions for causing a processor to implement a method, comprising:
directly coupling the read circuit to the data output register;
coupling the bypass control register to the row detector, the bypass control register issuing a bypass control signal to the row decoder, the bypass control signal comprising one of an active bypass signal and an inactive bypass signal;
if the bypass signal is inactive, one of a read operation and a write-through operation without bypass is permitted; and
if the bypass signal issued is active, a write-through operation is performed in bypass mode.

12. The computer program product of claim 11, wherein the read operation includes:
receiving a binary address from the address register by the row decoder;
the row decoder outputting an active signal onto a wordline associated with the circuit array;
at least one memory cell associated with the wordline providing a weak signal to bitline pairs associated with the circuit array; and
in response to receiving the weak signal by the read circuit, the read circuit provides an input to the data output register.

13. The computer program product of claim 11, wherein the write-through operation with bypass includes:
receiving a binary address from the address register by the row decoder;
in response to receiving the active bypass signal from the bypass control register, the row decoder refrains from outputting an active signal onto a wordline associated with the circuit array;
the write control register issuing an active write signal to the write circuit;
in response to the active write signal, the data input register sends binary values to the write circuit;
in response to receiving the binary values, the write circuit issues a strong differential signal to bitline pairs associated with the circuit array, the strong differential signal overpowering any weak signals at the circuit array, if provided;
passing the strong differential signal through the bitline pairs to the read circuit; and
transmitting the resultant signal to the data output register.

14. The computer program product of claim 13, wherein the row decoder refrains from outputting an active signal onto a wordline via a modified clock chopper component associated with the row decoder.

15. The computer program product of claim 14, wherein the modified clock chopper component includes a disable input pin operable for causing a delay element of the modified clock chopper to force an input of a logic gate to be low in the presence of an active bypass signal on the disable input pin of the delay element.
